(19) United States
(12) Patent Application Publication
(10) Pub. No.: US 2025/0386527 A1
(43) Pub. Date: Dec. 18, 2025

(54) NANOTEXTURED CAPACITORS AND METHODS OF FORMING THE SAME

(71) Applicant: ADEIA SEMICONDUCTOR BONDING TECHNOLOGIES INC., San Jose, CA (US)

(72) Inventors: Cyprian Emeka Uzoh, San Jose, CA (US); Oliver Zhao, Daly, CA (US); Arianna M. Avellán Jaramillo, Fremont, CA (US); Long Huynh, Santa Clara, CA (US)

(21) Appl. No.: 18/743,578

(22) Filed: Jun. 14, 2024

(51) Int. Cl. H10D 1/68

(52) U.S. Cl. CPC H10D 1/712

(57) ABSTRACT

Electrodes for a capacitor having nanotextured surfaces is disclosed. The nanotextured surfaces comprise nanograins of the metal and are fabricated by oxidizing and reducing a metal in the electrodes. The nanotextured surfaces significantly increase surface areas of the electrodes, as such improves a capacitance of the capacitor. The fabrication method can produce stacked capacitors with horizontally oriented electrodes or vertically oriented electrodes. The fabrication method may be of low cost and may produce high performance capacitors.

### BACKGROUND

### Field

The field relates to electronic components of microelectronics, and more particularly to capacitors in semiconductor elements.

### Description of the Related Art

A microelectronic device, e.g., an integrated circuit (“IC”), is a small electronic device comprising a huge number of interconnected tiny active and passive electronic components such as resistors, transistors, inductors, and capacitors. These components are built onto a piece of semiconductor substrate, usually silicon. Microelectronic devices, especially ICs, are used in a wide range of electronic applications, including computers, smartphones, appliances, automobiles, and televisions, to perform various functions such as processing and storing information.

Over the past decades the microelectronics industry has experienced tremendous growth. The integration density has got ever higher and technology node ever smaller. The industry has met the continuous challenge to build electronic components in semiconductor materials with smaller and smaller node dimensions, and is expected to continue to do so in the future.

As an important semiconductor component, capacitor is an electronic component that stores electrical energy by accumulating electric charges on two closely spaced conductive plates or electrodes each with a conductive surface facing each other. The conductive plates are typically insulated from each other by a dielectric or non-conductive material. Capacitance C of a capacitor, which is defined as a ratio of the electric charge and the voltage applied across the conductive surfaces, is expressed by the following equation:

C=εA/d

where A is the area of each conductive surfaces, d is the distance between the opposing conductive surfaces, and ε=ε₀εᵣ, where ε is the absolute permittivity of the dielectric or non-conductive material disposed between the conductive plates, ε is the vacuum permittivity, and ε is the relative permittivity, which is the ratio of the absolute permittivity ε and co.

According to the equation above, capacitance of a capacitor increases with the area, A, of the conductive surfaces that form the capacitor and decreases with the distance, d, between the surfaces. Thus, one technique for increasing capacitance is increasing the area of the conductive surfaces, hence benefitting the demand of increasing integration density for ICs.

### BRIEF DESCRIPTION OF THE DRAWINGS

Specific implementations will now be described with reference to the following drawings, which are provided by way of example, and not limitation.

FIG. 1 is a schematic cross-sectional view of a partially fabricated substrate, illustrating an example process stage for providing a conductive layer over a base substrate of a semiconductor element.

FIG. 2 is a schematic cross-sectional view illustrating an example process stage for providing a patterned mask layer over the conductive layer of the semiconductor element of FIG. 1.

FIG. 3 is a schematic cross-sectional view illustrating an example process stage for oxidizing a metal in the conductive layer of FIG. 2 for forming a nanotextured upper surface comprising nanograins of metal oxide.

FIG. 4 is a chart illustrating a relationship between surface roughness and ashing time after the semiconductor element of FIG. 3 is subjected to an ashing process.

FIG. 5 is a schematic cross-sectional view illustrating an example process stage for reducing the metal oxide in the conductive layer of FIG. 3 to metal while preserving a nanotextured upper surface.

FIG. 6 is a chart illustrating a relationship between surface roughness and forming gas annealing time after the semiconductor element of FIG. 6 is subjected a forming gas annealing process.

FIG. 7 is an SEM image of the upper surface of the semiconductor element of FIG. 1 before oxidizing and reducing.

FIG. 8 is an SEM image of the upper surface of the semiconductor element of FIG. 5 after the ashing process of FIG. 4 and the forming gas annealing process of FIG. 6.

FIG. 9 is an SEM image of the upper surface of the semiconductor element of FIG. 5 after the ashing process of FIG. 4 and the forming gas annealing process of FIG. 6.

FIG. 10 is a schematic plan view illustrating an example nanotextured upper surface of the conductive layer of FIG. 5, having nanograins formed thereon.

FIG. 11 is a schematic cross-sectional view illustrating a nanograin partially protruding out of the upper surface of FIG. 10.

FIG. 12 is a schematic cross-sectional view illustrating an example process stage for providing a dielectric layer over the nanotextured surface of the conductive layer of FIG. 5.

FIG. 13 is a schematic cross-sectional view illustrating an example process stage for providing an upper conductive layer over the dielectric layer of FIG. 12.

FIG. 14 is a schematic cross-sectional view illustrating an example process stage for providing a patterned mask over the upper conductive layer of FIG. 13.

FIG. 15 is a schematic cross-sectional view illustrating an example process stage for etching through the upper conductive layer and the dielectric layer of FIG. 14 to create a contact for the lower conductive plate.

FIG. 16 is a schematic cross-sectional view illustrating an example semiconductor element of FIG. 15 connected to a circuit to function as a capacitor.

FIG. 17 is a flowchart illustrating a fabrication method for forming a capacitor, in accordance with some embodiments.

FIG. 18 is a flowchart illustrating a fabrication method for forming vertically stacked capacitors.

FIG. 19 is schematic cross-sectional view of an example capacitor formed by the fabrication method of FIG. 18.

FIG. 20 is a schematic cross-sectional view illustrating an example process stage for providing a patterned mask over the conductive layer of the semiconductor element of FIG. 1.

FIG. 21 is a schematic cross-sectional view illustrating an example process stage for etching the conductive layer of FIG. 20 for forming a plurality of cavities in the conductive layer.

FIG. 22 is a schematic cross-sectional view illustrating example process stages for oxidizing and reducing a metal in the conductive layer of FIG. 21 for forming nanotextured surfaces comprising nanograins.

FIG. 23 is a schematic cross-sectional view illustrating an example process stage for overfilling the cavities in the conductive layer of FIG. 22 with a dielectric material.

FIG. 24 is a schematic cross-sectional view illustrating an example process stage for removing the excess dielectric material and planarizing an upper surface of the semiconductor element of FIG. 23.

FIG. 25 is a flowchart illustrating a fabrication method for forming horizontally stacked capacitor plates, in accordance with some embodiments.

FIG. 26 is a schematic cross-sectional perspective view of a semiconductor element showing example horizontally stacked capacitor plates in accordance with the process of FIG. 25.

FIG. 27 is schematic a detailed cross-sectional view of the semiconductor element of FIG. 26 showing nanotextured surfaces of capacitor electrodes.

FIG. 28 is a schematic cross-sectional perspective view of horizontally stacked capacitor plates in accordance with a variant of FIG. 26.

FIG. 29 is a schematic plan view of a capacitor element comprising interdigitated electrodes, in accordance with an embodiment.

FIG. 30 is a schematic cross-sectional view of a capacitor element comprising three-dimensionally folding electrodes and dielectric material.

FIG. 31 is a schematic cross-sectional view of a semiconductor element comprising conductive features embedded in a dielectric layer.

### DETAILED DESCRIPTION

There are many ways to increase the surface area of capacitors in microelectronic devices. For example, nano wires or nano tubes can be formed on the surfaces of the capacitor plates to increase the surface area. Graphene material can be adopted to increase the capacitor area. Porous metal or foam can be applied to the surfaces of the capacitor plates to increase the surface area. However, such methods may be complicated and expensive to implement.

The present disclosure provides structures and fabrication methods of nanotextured conductive surfaces for microelectronic components, e.g., capacitors. As described herein, the nanotextured conductive surfaces can significantly increase surface areas, and can be applied to improve numerous forms of existing capacitors, e.g., parallel horizontal plate capacitors, vertical plate capacitors, three-dimensional folding capacitors, and stacked capacitors, etc.

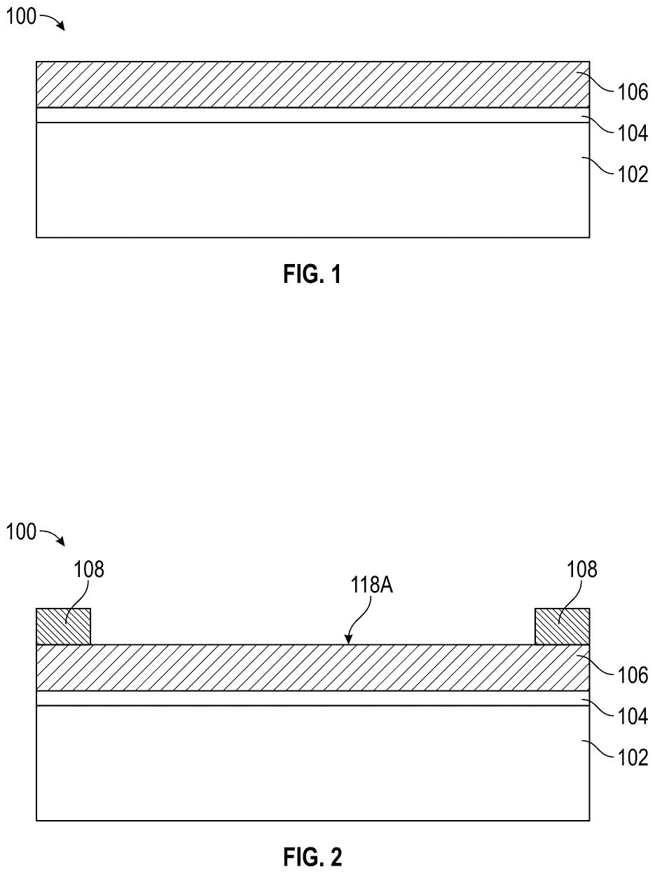

An example embodiment of a fabrication process for forming a microstructure for conductive surfaces, such as conductive plates or electrodes for capacitors, is described herein with respect to illustrated figures and charts. FIG. 1 shows a schematic cross-sectional view of at least a portion of a partially fabricated semiconductor element 100, such as a microelectronic structure, a microelectronic element or a semiconductor device. The semiconductor element 100 can comprise a base substrate 102, such as a bulk semiconductor material (e.g., single crystal silicon), an interposer substrate, a semiconductor package substrate, a flat panel substrate, an organic substrate, or a dielectric (e.g., glass or quartz) substrate. The base substrate 102 can comprise active circuitry and/or other devices formed at least partially therein. A base nonconductive or dielectric layer 104 may be deposited over the base substrate 102. A first conductive layer 106 (e.g., a bottom or lower conductive layer) may be deposited over the dielectric layer 104. The first conductive layer 106 can be deposited using a metal organic chemical vapor deposition (MOCVD) process, a physical vapor deposition (PVD) process, a sputtering process, or a solgel process (e.g., spin on and cure). In some embodiments, a barrier layer may be provided between the first conductive layer 106 and the underlying dielectric layer 104 to limit diffusion of the conductive material of the first conductive layer 106 into the dielectric layer 104 and to serve as an adhesion layer therebetween. In some embodiments, a seed layer may be disposed on the barrier layer, such as by copper sputtering.

In some embodiments, under the first conductive layer 106 the semiconductor element 100 can have a more complicated structure, with three-dimensional folding shapes, such as container-shapes (e.g., cylinders), pillars, and/or fins. The first conductive layer 106 can connect to underlying circuitry, e.g., through vias (not shown) through the dielectric layer 104. The first conductive layer 106 can comprise a metal, such as copper, nickel, chromium, gold, indium, tin, platinum, silver, ruthenium, molybdenum, palladium, cobalt, zinc, tungsten, tantalum, titanium, aluminum, a metal silicide, and alloys thereof.

The first conductive layer 106 may be characterized by a crystalline microstructure with grains and boundaries. For example, the first conductive layer 106 may comprise copper in which the average grain size of the crystalline structure may range from 0.2 μm to 5 μm or even larger. Factors that can influence grain size of the crystal structure in a conductive layer may include material composition, dimensions including thickness, width and length of the conductive layer, and thermal history of the conductive layer. For example, grain size may be bigger for a wider conductive layer. For example, with respect to material composition, a conventionally coated copper, nickel, chromium, aluminum, tantalum, or titanium conductive layer may comprise less than 100 ppm (e.g., less than 50 ppm, or less than 10 ppm) impurity content.

Referring to FIG. 2, a patterned mask 108 is formed over the first conductive layer 106 of the semiconductor element 100. For example, a mask layer is deposited and patterned to expose at least a portion of a surface 118A of the first conductive layer 106.

Subsequently, the semiconductor element 100 is exposed to an oxidation environment that chemically oxidizes the metal on the exposed surface 118A of the first conductive layer 106 of FIG. 2. The chemical oxidation process can be plasma oxidization (e.g., by exposure to an oxygen-containing plasma), thermal oxidization, ozone exposure, or wet oxidation (e.g., by exposure to inorganic or organic peroxides). For example, the semiconductor element 100 of FIG. 2 can be subjected to a plasma ashing process, in which products of oxygen-containing plasma are supplied to the semiconductor element 100. Such a process is referred to as “ashing” because it is traditionally employed for burning off organic photoresist. During the oxidation process, oxygen initially reacts with the metal exposed at the surface 118A as shown in FIG. 2 to form a surface metal oxide. As time goes by, oxygen penetrates into the first conductive layer 106 through diffusion, causing metal oxide to form in an upper portion 112 of the first conductive layer 106. The oxygen content in the upper portion 112 may decrease with a depth from the surface 118, and the upper portion 112 may grow thicker as time goes by.

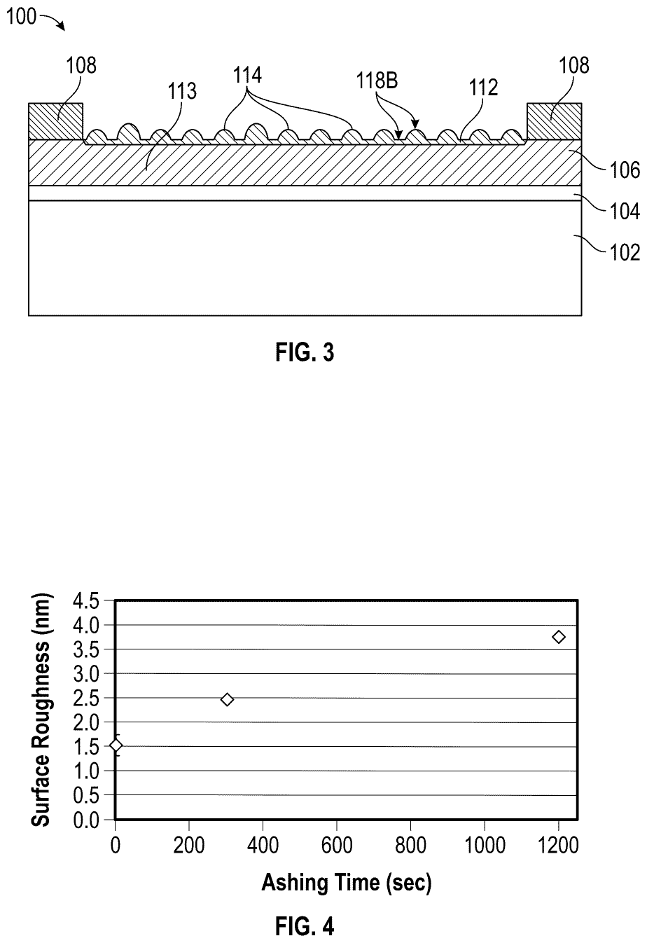

When oxygen reacts with a metal to form a metal oxide, e.g., copper oxide, nickel oxide or tantalum oxide, the metal oxide may nucleate locally to form tiny metal oxide particles or grains, e.g., nanograins. As shown in FIG. 3, as time goes by, more nanograins of metal oxide may nucleate, and the nanograins already formed may grow bigger in size. Certain metal oxide nanograins 114, that may resemble a powder, flakes, needle like, or grains with spherical or non-spherical shapes, may protrude out and modify the texture of the surface 118A to form a micro surface structure or a nanotextured surface appearance, as such transforming the surface 118A, to a nanotextured surface 118B having protrusions on the order of nanometers. As illustrated in FIG. 3, the formed metal oxide nanograins 114 covers part of the surface area. Such nanotextured surface 118B with nanotextured appearance clearly differs from the flat and smooth surface 118A before the oxidation process, as will be further described subsequently. The nanotextured surface 118B can be characterized by nanograins or nano-protrusions having diameters typically less than 100 nm, e.g., between 3 nm to 90 nm, or between 10 to 70 nm. Another way to characterize the nanotextured surface 118B is by surface roughness, as measured by Root Mean Square (RMS) in nanometer. FIG. 4 is a chart showing experimental measurement results of surface roughness after test samples went through different ashing time. As shown in FIG. 4, with no ashing, that is, ashing time=0 second, the surface roughness is about 1.5 nm. When ashing time increases to about 300 seconds, the surface roughness is about 2.5 nm. When ashing time increases to about 1200 seconds, the surface roughness increases to about 3.8 nm. The ashing process is typically controlled at a power in a range of about 50 W-300 W, oxygen flow rate in a range of about 50 sccm-300 sccm, and a pressure in a range of about 100 milliTorr-500 milliTorr. In some embodiments, substrate temperature is not temperature-controlled during the ashing process. In other embodiments, temperature control can add a variable for process control. The measurement data plotted in FIG. 4 indicates that a longer exposure of the surface 118B to the ashing environment causes the metal oxide nanograins to grow bigger. Another consequence of longer exposure times may be forming more nanograins on the surface 118B and in the upper portion 112, which is not presented in FIG. 4. Thus, as time goes by, the appearance of the nanotextured surface 118B may be characterized by more and bigger nanograins, leading to increased surface area. Beyond a certain point, depending on the porosity of the formed metal oxide and diffusion of oxygen species of the oxygen plasma, increased oxidation time will have diminishing returns, as agglomeration of oxide particles can reduce grain density and thus surface area.

Over time, oxygen penetrates the surface 118B and diffuses at least into the upper portion or sublayer 112 of the first conductive layer 106. Below the upper portion 112 is a lower portion 113 of the first conductive layer 106 that receives less diffused oxygen or has not received diffused oxygen. As time goes by, the depth of the oxygen diffusion increases, and the upper portion 112 grows thicker. Within the upper portion 112, oxygen reacts with the metal therein to form nanograins of metal oxide. Because of the nature of diffusion, oxygen content is the highest at the surface 118B, decreases along a direction from the surface 118B toward the lower portion 113, and becomes the lowest when reaching the lower portion 113. Therefore, a density of the nanograins of metal oxide formed, or number of nanograins of metal oxide per unit volume, is the greatest at the surface 118B, decreases along the direction from the surface 118B toward the lower portion 113, and becomes the smallest when reaching the lower portion 113. Meanwhile the density of the larger metal grains existing from before the oxidation process transitions from a lower lever at the surface 118B, increases in the same direction from the surface 118B toward the lower portion 113, and reaches the pre oxidation level in the lower portion 113. This means that the density of the nanograins in the upper portion 112 may have a non-uniform distribution in the direction from the surface 118B to the lower portion 113.

Referring back to the embodiment shown in FIG. 3, the metal oxide nanograins 114 are formed by oxidation of the metal on the surface 118B and into the depth of the upper portion 112 of the first conductive layer 106. However, the upper portion 112 with the surface 118B comprising metal oxide grains can be formed in other ways. For example, the upper portion 112 can be deposited on the first conductive layer 106 by sputtering (e.g., reactive sputtering) metal grains (e.g., copper grains) in an oxidizing ambient, such as an oxygen and argon ambient at a pressure (e.g., at 0.05 Torr to 5 Torr) that promotes collision between the sputtered copper and oxygen to form nanograin copper oxide. At least part of the sputtered copper is oxidized to form the upper portion 112. The formed surface 118B thus comprises a nanotextured appearance having nanograins of metal oxide. The sputtering process may be controlled to form metal oxide nanograins of a desired size, e.g., an average size (e.g., average of a maximum grain dimension) in the range of about 2 nm to 100 nm (e.g., an average size in a range of about 8 nm to 80 nm, or in a range of about 5 nm to 50 nm).

Nevertheless, the nanotextured surface 118B formed by such sputtering process may be different from the nanotextured surface 118B formed by oxidation as described with respect to FIG. 3. For example, for the oxidation process, the size of the metal oxide nanograins on the surface 118B can be controlled by process parameters, e.g., ashing time, chamber pressure, oxygen flow rate or partial pressure, power, bias on the substrate, amongst others. But for the reactive sputtering process, the size of the metal oxide nanograins may depend on the size of the sputtered metal grains, which in turn may depend on reactive sputtering parameters. Furthermore, different oxidation agents, for example, products of direct or remote oxygen plasma, thermal oxidation, wet chemical oxidation, or electrolytic oxidation, may cause different and unique nanotexture signatures. If the oxide grains are deposited, e.g., by reactive sputtering, the surface may show unique signature of the specific deposition process, for example, packed nanograins including the metal oxide grains. Another difference may be that while in the oxidation process the metal that forms the metal oxide in the upper portion 112 is the same as a metal in the lower portion 113 of the first conductive layer 106, oxidized metal of the reactive sputtering process can be different from the metal in the lower portion 113 of the first conductive layer 106. For example, the lower portion 113 may comprise copper and the metal oxide in the upper portion 112 may comprise nickel or aluminum oxide.

Furthermore, for the sputtering process the density of the nanograins of metal oxide within the upper portion 112 may be controlled to be more uniform compared to the nanograin distribution for the oxidation process.

Generally speaking, at least part of a conductive material on the surface 118A and in the upper portion 112 of the first conductive layer 106 can be chemically converted to a compound of the conductive material that has a nanograin structure, thereby converting the smooth surface 118A to the nanotextured surface 118B. Chemical oxidation of metal to metal oxide is an example of chemical conversion of conductive material to compound of the conductive material.

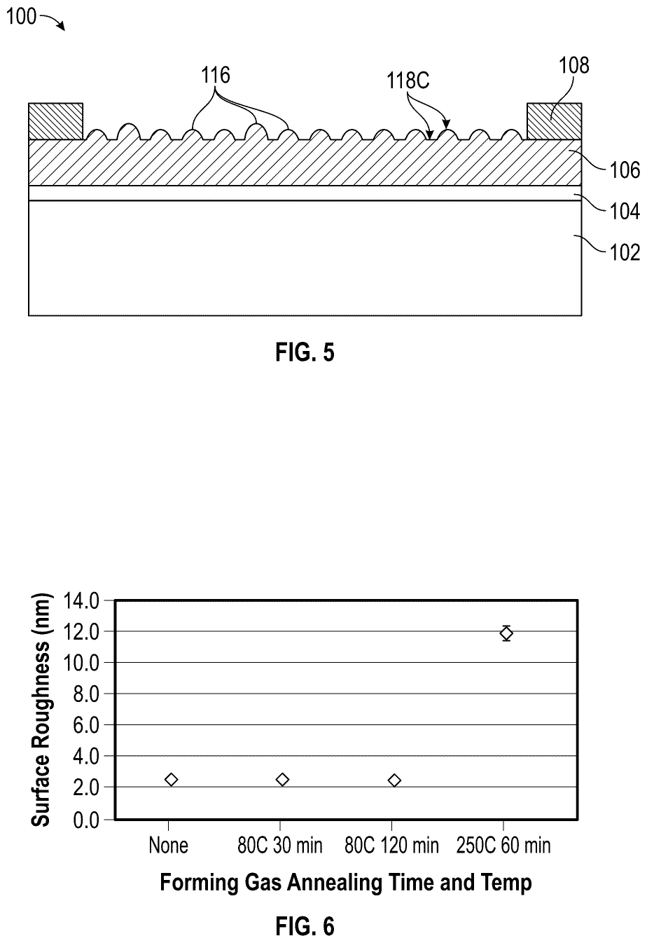

Referring now to FIG. 5, the semiconductor element 100 is exposed to an environment to chemically reduce, e.g., electrochemically reduce, the metal oxide, including the metal oxide nanograins 114 on the surface 118B and in the upper portion 112, to the metal. The chemical reduction can be accomplished by exposure to a reducing environment or ambient, such as, for example, hydrogen-containing plasma, water vapor plasma, hydrogen gas, ammonia gas, forming gas (N₂/H₂), or combinations thereof. Consequently, the upper portion 112 comprising the metal oxide may be at least partially transformed to the metal, forming part of the first conductive layer 106 comprising the metal, as shown in FIG. 5. After the reduction process, a surface 118C is left having a nanotextured appearance comprising metal nanograins 116 that may resemble the appearance of the metal oxide nanograins 114. Depending on the thoroughness of the reduction process, part of the metal oxide nanograins 114 formed after the oxidation process may remain on the surface 118 together with the metal nanograins 116.

Within the upper portion 112 of the conductive layer 106, after the chemical reduction process, the metal oxide nanograins may be reduced to nanograins of the metal. Also, depending on the thoroughness of the reduction, some metal oxide may remain. Therefore, the residual oxygen content in the upper portion 112 may be higher than a conductive layer formed by a conventional method, for example greater than 100 ppm.

The metal oxide reduction process may comprise an annealing process in a reducing environment, such as with forming gas at an elevated temperature for a predetermined duration, e.g., at about 50° C.-400° C. for about 2-90 minutes, or at about 80° C.-250° C. for about 5-60 minutes). It is noted that the temperature and duration of the reduction annealing may differ depending upon the reducing strength of the reducing environment. The metal oxide reduction process may be accomplished under atmospheric pressure, in a reducing liquid or fluid, or in vacuum with a hydrogen-including plasma. For example, excited hydrogen species from such a plasma can reduce the metal oxide to metal at a temperature ranging between 0° C. to 180° C. and under a pressure ranging from about 1-50,000 milliTorr, e.g., about 10-1000 milliTorr.

Again, the chemical reduction process may be considered a special case of a general chemical reaction to at least partially convert the compound of the conductive material back to the conductive material. After the conversion process, the nanotextured surface 118B is converted to a nanotextured surface 118C to at least partially preserve the nanograin surface structure of the surface 118B.

Similar to the nanotextured surface after oxidation, the nanotextured surface after annealing can be characterized by average grain size (e.g., average of maximum grain dimension) of the nanograins on the surface or by surface roughness as measured by RMS. Experiments were conducted to measure the surface roughness of the nanotextured surface before and after the forming gas annealing processes. FIG. 6 is a chart showing surface roughness data resulting from four different reduction process conditions: no forming gas annealing (representing un-reduced metal oxide grains), forming gas annealing at 80° C. for 30 minutes, at 80° C. for 120 minutes, and at 250° C. for 60 minutes. According to Arrhenius law, higher annealing temperature may increase chemical reaction causing the metal oxide to reduce to the metal more rapidly and more thoroughly. Furthermore, higher temperature of annealing can enhance migration of metal atoms and molecules. This enhanced migration may cause the nanograins of the reduced metal to grow bigger or to conglomerate. The net effect is bigger (and possibly fewer) nanograins. As shown in FIG. 6, when there is no forming gas annealing, the surface roughness of the nanotextured surface is about 2.5 nm RMS, consistent with the surface roughness shown in FIG. 4 for the data point of ashing for about 300 seconds. When the annealing temperature is at 80° C. and annealing duration increases from 30 minutes to 120 minutes, the surface roughness of the nanotextured surface remains at about 2.5 nm RMS, as shown in FIG. 6. Therefore, at a temperature equal to or below 80° C., forming gas annealing does not increase surface roughness with increased reduction duration. However, as shown by the right most point in FIG. 6, when annealing temperature is increased to about 250° C. for 60 minutes, surface roughness of the nanotextured surface increases to an average of about 12 nm RMS±about 1 nm RMS. Therefore, at 250° C. the reduction reaction and thermal migration cause the nanograins of the nanotextured surface to grow bigger.

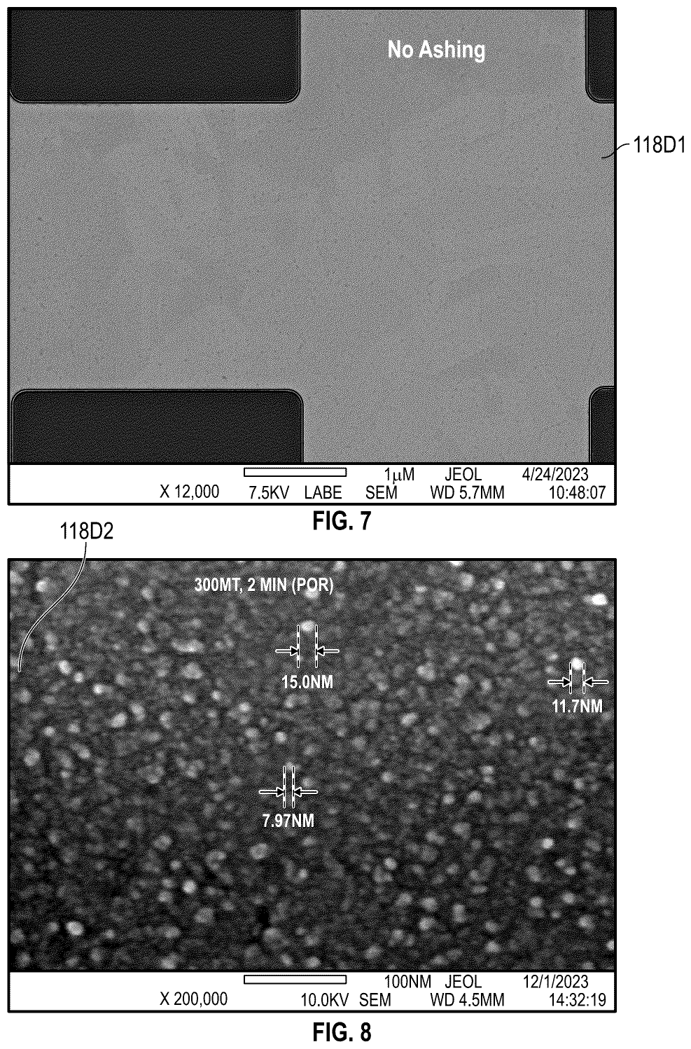

FIGS. 7-9 show scanning electron microscope (SEM) images of surfaces 118D (e.g., 118D1-118D3) of the first conductive layer for different test samples, each of which went through different processing conditions. As indicated by the text in the SEM image of FIG. 7, the test sample did not go through the oxidation process, e.g., ashing, nor the reduction process, e.g., forming gas annealing. The surface 118D1 of the first conductive layer, as shown in FIG. 7 as a light gray region, is smooth and uniform, indicating a planarized metal surface, e.g., at the state illustrated in FIG. 1 or FIG. 2.

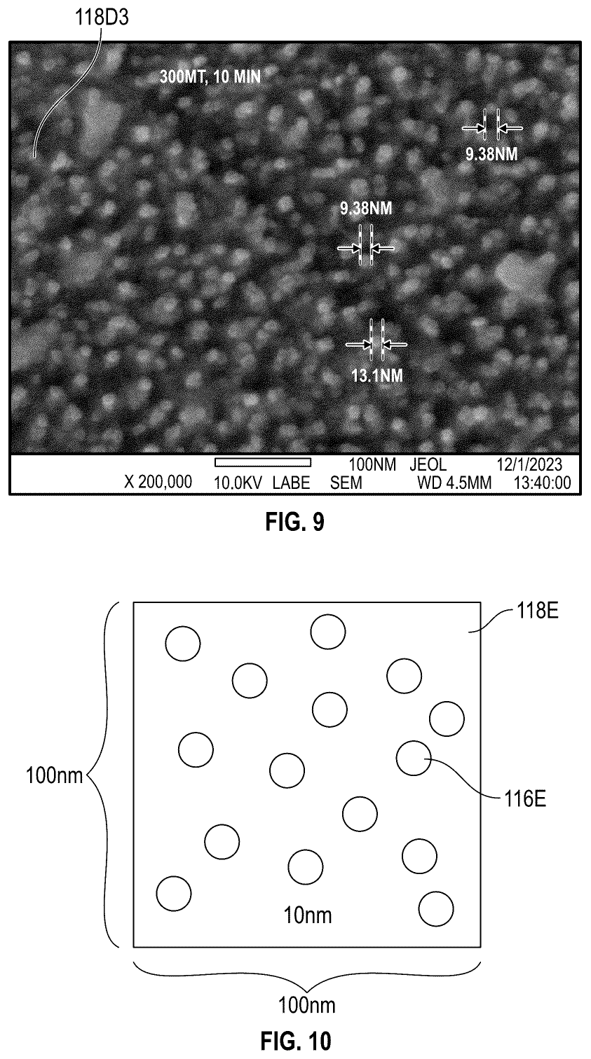

The test sample shown in FIG. 8 went through ashing at 300 milliTorr for 2 minutes and followed by forming gas annealing at 250° C. As shown in FIG. 8, the surface 118D2 has a grainy texture. Measurements shown in FIG. 8 indicate that the width of the nanograins on the surface 118D2 ranges from 7.97 nm to 15 nm. In FIG. 9, the test sample went through ashing at 300 milliTorr for 10 minutes and followed by forming gas annealing at 250° C. The measured grain size data shown in FIG. 9 on the surface 118D3 range from 9.38 nm to 13.1 nm. The grain sizes shown in FIG. 8 for 2 minutes ashing and the grain sizes shown in FIG. 9 for 10 minutes ashing overlap with one another. However, FIG. 9 also shows a few larger islands indicating possible grain conglomerations due to longer ashing duration. Therefore, nanograins on the surface 118D of the conductive layer may grow bigger as ashing duration goes longer.

As shown in the SEM images of FIGS. 8 and 9, nanograins are scattered on the surfaces 118D2 and 118D3. The nanograins may cover more than 50% of the surface 118D2 or 118D3, e.g., about 60% to 100% of the surface 118D2 or 118D3, or 80% to 100% of the surface 118D2 or 118D3, such as about 50% to 95% of the surface, or about 60% to 90% of the surface. The nanograins protrude out of the surface 118D2 or 118D3, forming a 3D topological surface structure. As such the surface area of the 3D nanograins protruding out of each of the surface 118D2 or 118D3 is greater than the area of the flat surface the nanograins occupy.

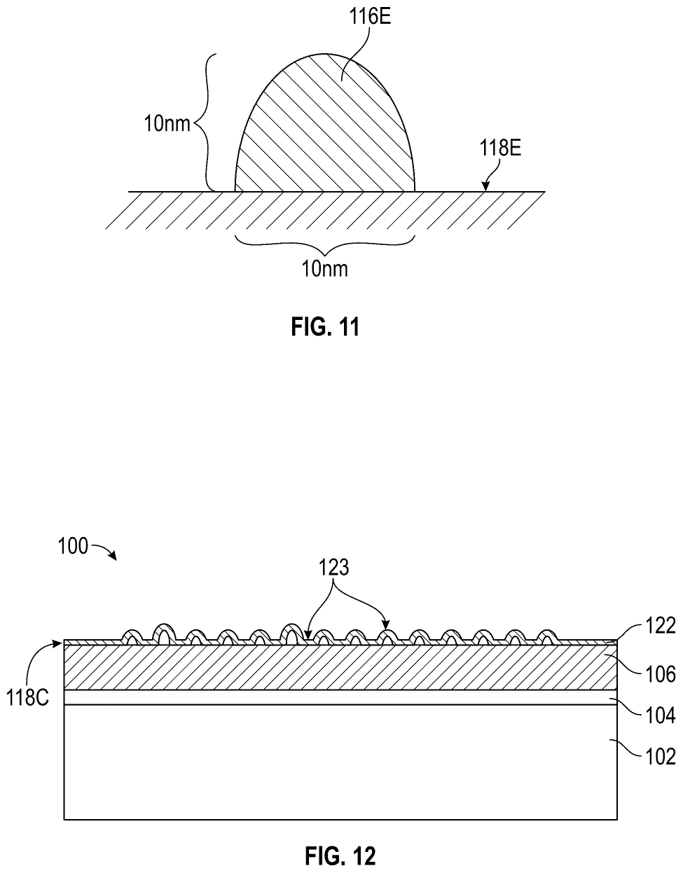

To calculate the increase of the surface area by having the protruding nanograins on a flat surface, FIG. 10 schematically illustrates an example nanotextured square surface 118E that is 100 nm by 100 nm in size. The square surface 118E has 15 separate nanograins 116E formed thereon, as approximated by the nanograin density in FIG. 9, expanding the flat surface to a 3D topological surface structure. Each of the nanograins 116E has a diameter of 10 nm, and is ellipsoid shaped, e.g., elongated or spherical. FIG. 11 is a schematic cross-sectional view of one of the nanograins 116E shown in FIG. 10. The ellipsoid nanograin 116E has an elongate elliptical cross-sectional area when cut perpendicular to a long axis of the nanograin 116E. Further, the long axis is about twice as long as a short axis of the nanograin 116E. Thus, the portion of the nanograin 116B protruding out of the flat surface is 10 nm high, which is the same is the diameter or width of the nanograin 116E, as illustrated in FIG. 11. Calculations show that the total surface area of the half domed ellipsoid nanograin 116E is about 268 nm². Thus, for the example nanotextured surface 118E illustrated in FIGS. 10 and 11 having 15 nanograins 116E formed thereon (corresponding to about 11.8% of flat surface area occupied by the nanograins), the area increase of the surface 118E is about 29% over the area of the 100 nm square flat surface. When the number of nanograins 116E is increased to cover 50% of the flat surface area, which is equivalent to about 63.7 nanograins 116E, calculations reveal that the area increase of the surface 118E is about 121%. For 60% flat area coverage, which is equivalent to about 76.4 nanograins 116E, the area increase is about 145%. Furthermore, for 80% flat area coverage, which is equivalent to about 101.9 nanograins 116E, the area increase is about 213%. Therefore, forming nanograins on the surface 118E can significantly increase the surface area. It is noted that for the same area coverage of the nanograins 116E, a smaller nanograin diameter corresponds to a greater number of nanograins on the surface and a higher area increase. It will be appreciated that the ellipsoid shaped nanograins 116E illustrated FIGS. 10 and 11 are for simplicity of analysis and nanograins in other shapes will have similar effect of increasing surface area.

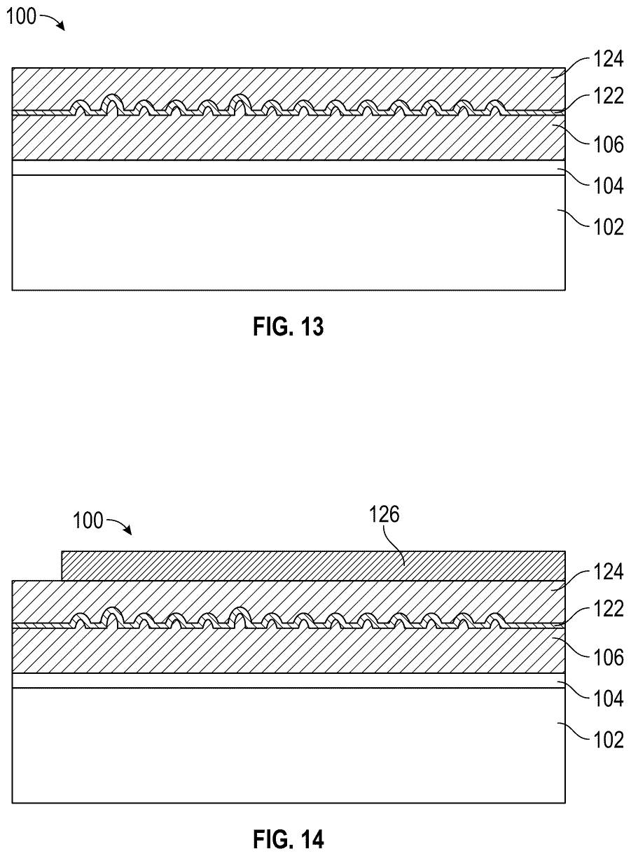

Referring to FIG. 12, a capacitor dielectric layer 122, which can also be referred to as a first dielectric layer 122, is formed over the surface 118C of the first conductive layer 106. The capacitor dielectric layer 122 may comprise silicon nitride (SiN), hafnium oxide (HfO, such as HfO₂), aluminum oxide (AlO, such as Al₂O₃), tantalum oxide, titanium oxide, strontium titanate, barium strontium titanate, calcium copper titanate, or combinations thereof. Beneficially, the dielectric material of the capacitor dielectric layer 122 may have a dielectric constant greater than 5, greater than 10, greater than 20, greater than 100, or greater than 200, as with some ternary high k materials. The capacitor dielectric layer 122 may be deposited by atomic layer deposition (ALD) method, chemical vapor deposition (CVD) method, PVD, power sintering or another suitable method, to form a conformal dielectric layer of a substantially uniform thickness. The thickness of such formed capacitor dielectric layer 122 may be less than 50 nm, such as less than 20 nm, or less than 10 nm. As such the nanotextured appearance of the surface 118C formed from the flat surface portion and the nanograins 116 as described above is transferred through the substantially uniform thickness of the dielectric layer 122 to a surface 123 of the capacitor dielectric layer 122. Subsequently, a second conductive layer 124 may be deposited over the capacitor dielectric layer 122, as shown in FIG. 13. The second conductive layer 124 may comprise a metal, such as copper, nickel, chromium, gold, indium, tin, platinum, silver, ruthenium, molybdenum, palladium, cobalt, zinc, tungsten, tantalum, titanium, aluminum, a metal silicide, and alloys thereof. As can be seen in FIG. 13, a lower surface of the second conductive layer 124 is mated with or molded from the nanotextured surface 123 of the first dielectric layer 122, due to the deposition process. Thus, the lower surface of the second conductive layer 124 has increased surface area equivalent or similar to the surface 118C of the first conductive layer 106.

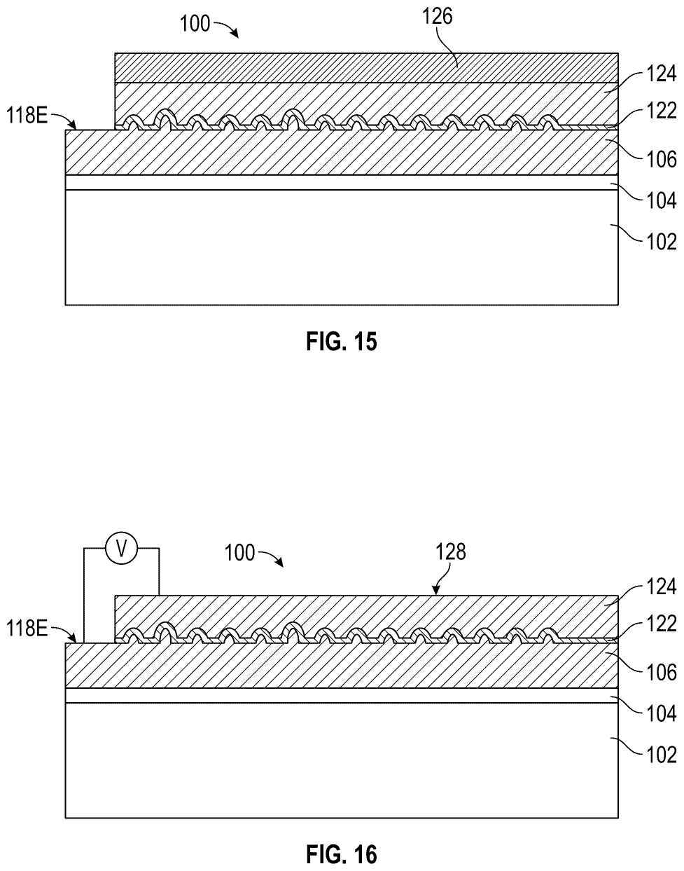

In FIG. 14, a mask 126, such as photoresist, may be deposited over the second conductive layer 124 and patterned. In FIG. 15, the second conductive layer 124 and the capacitor dielectric layer 122 are etched to expose the surface 118C of the first conductive layer 106. As illustrated in FIG. 16, after removing the mask 126 to expose contacts, the first conductive layer 106 and the second conductive layer 124 can be electrically connected to a circuit applying a voltage difference across the plates to function as two parallel conductive plates or electrodes of a capacitor, with the first conductive layer 106 functioning as a first electrode and the second conductive layer 124 functioning as a second electrode for the capacitor. As discussed above, the areas of the facing surfaces of the first conductive layer 106 and the second conductive layer 124 are significantly increased by nanotexturing disclosed herein. As such, the capacitance of the capacitor is significantly increased.

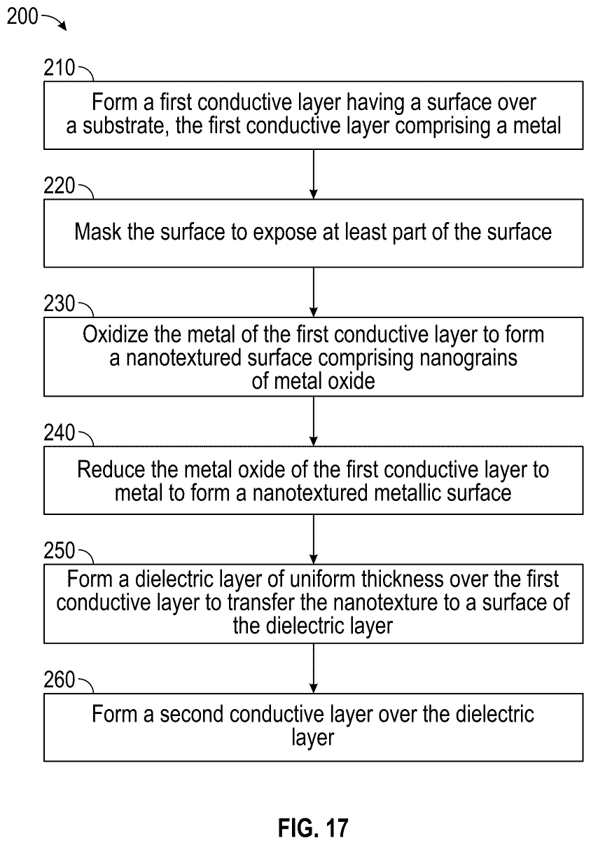

The fabrication method to produce a capacitor with increased capacitance described above with respect to FIGS. 1-13 are further illustrated as a process flowchart 200 shown in FIG. 17. According to the process flowchart 200, at block 210 a first conductive layer having a surface is formed over a semiconductor substrate for a microelectronic element. The first conductive layer comprises a metal. At block 220, the microelectronic element is masked to expose at least part of the surface of the first conductive layer. At block 230, the metal at the exposed surface and in the first conductive layer is oxidized to form a nanotextured surface comprising nanograins of metal oxide. In other embodiments, a conductive material on the surface and in the first conductive layer may be exposed to other reactants to form a compound having nanotextured structure, forming a nanotextured surface. The nanotextured surface thus formed has significantly increased surface area compared with the flat surface without the nanograins, as described previously. At block 240, the metal compound, such as metal oxide, is electrochemically reduced or otherwise converted back to the metal or the conductive material, and a nanotextured metallic surface is left. At block 250, a dielectric layer of substantially uniform thickness is formed over the first conductive layer. The nanotextured metallic surface of the first conductive layer is transferred through the substantially uniform thickness of the dielectric layer to a surface of the dielectric layer. At block 260, a second conductive layer is formed over the dielectric layer.

The first conductive layer and the second conductive layer thus formed with the dielectric layer disposed therebetween can function as a capacitor with significantly increased capacitance and high performance because of the nanotextured surface structure. Other benefits of the nanotextured surface structure may include inexpensive fabrication cost, high fabrication yield, and very versatile fabrication and implementation. Advantageously, the capacitor dielectric can be directly deposited on the reduced nanotextured metallic surface without requiring an intervening metal deposition, which might degrade the surface enhancement. The nanotextured surface structure may be easily integrated into back end of line (BEOL), redistribution layer (RDL), and monolithic systems of a semiconductor element or microelectronic structure.

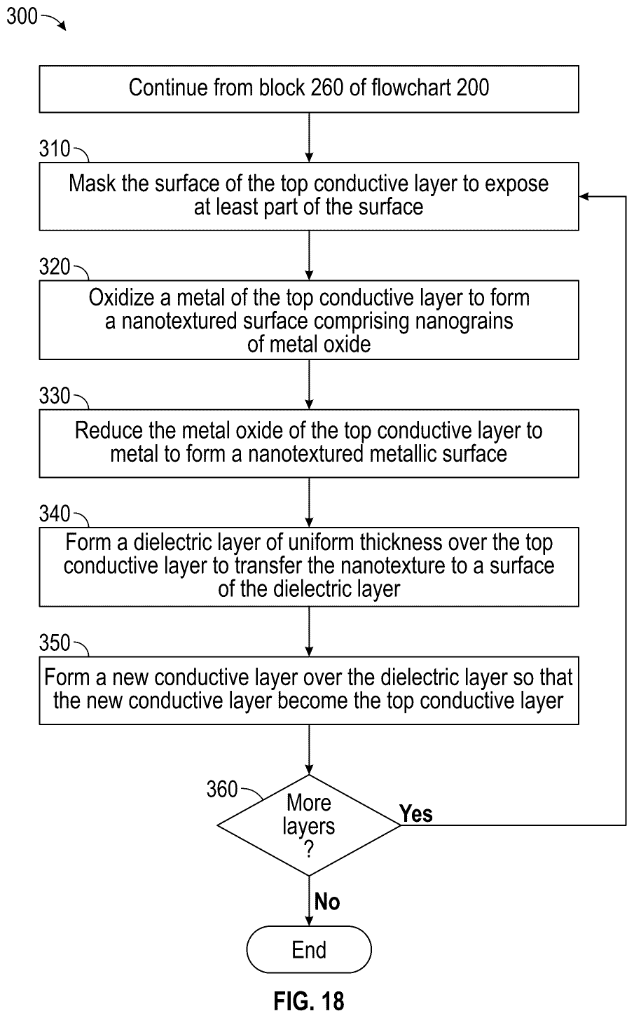

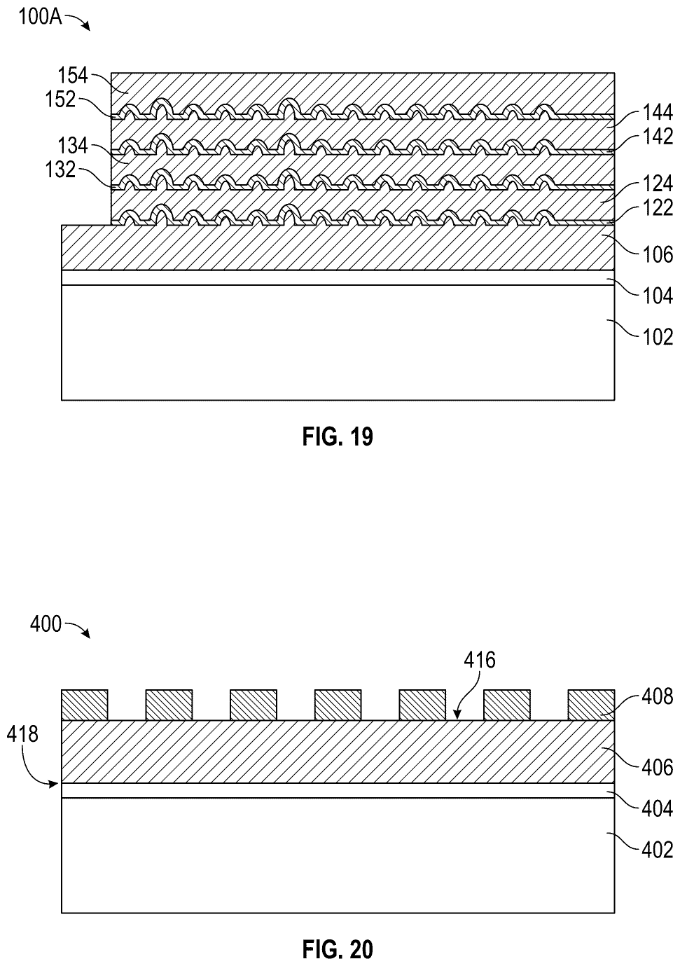

Referring to FIG. 18, a process flowchart 300 is illustrated to produce a semiconductor element 100A schematically illustrated in FIG. 19. As shown in FIG. 19, the semiconductor element 100A comprises extra layers of dielectric material and conductive material that are provided over the second conductive layer 124 of the semiconductor element 100 at a stage shown in FIG. 13.

The process flowchart 300 can be a continuation from the last step (e.g., block 260) of the process flowchart 200 shown in FIG. 17. At block 310, a surface of the top conductive layer of the semiconductor element 100A is masked and patterned to expose at least part of the surface. At block 320, a metal exposed at the surface and in the top conductive layer is oxidized to form a nanotextured surface comprising nanograins of metal oxide. The nanotextured surface thus formed has significantly increased surface area compared with a flat surface without the nanograins before oxidizing. At block 330, the metal oxide is reduced, and a nanotextured metallic surface is left. At block 340, a dielectric layer of substantially uniform thickness is formed over the top conductive layer. The nanotextured metallic surface of the top conductive layer is thus transferred to the dielectric layer. At block 350, another conductive layer is formed over the dielectric layer. This conductive layer thus becomes a new top conductive layer, and the surface of this new top conductive layer facing the previously formed dielectric is nanotextured. At block 360, a decision is made on whether additional conductive and dielectric layers are to be formed in the semiconductor element 100A. If the answer is yes, the process flow returns to block 310 to build more conductive and dielectric layers. If the answer is no, the process flow is terminated.

The semiconductor element 100A shown in FIG. 19 has three additional conductive layers, 134, 144, 154, and three additional dielectric layers, 132, 142, 152, as compared to the thin film structure shown in FIG. 13. A second dielectric layer 132 is disposed between the second conductive layer 124 and a third conductive layer 134. A third dielectric layer 142 is disposed between the third conductive layer 134 and a fourth conductive layer 144. A fourth dielectric layer 152 is disposed between the fourth conductive layer 144 and a fifth conductive layer 154. Therefore, across each of the dielectric layers 122, 132, 142, 152 are a pair of conductive layers that can function as electrodes for a capacitor. Conductive surfaces facing each dielectric layer are nanotextured conductive surfaces, as described above. For example, the first conductive layer 106 and the second conductive layer 124 with the first dielectric layer 122 disposed therebetween can function as electrodes for a first capacitor, as described with respect to FIG. 16. Likewise, the second conductive layer 124 and the third conductive layer 134 with the second dielectric layer 132 disposed therebetween can function as electrodes for a second capacitor; the third conductive layer 134 and the fourth conductive layer 144 with the third dielectric layer 142 disposed therebetween can function as electrodes for a third capacitor; the fourth conductive layer 144 and the fifth conductive layer 154 with the fourth dielectric layer 152 disposed therebetween can function as electrodes for a fourth capacitor. As such, a vertical stack of four horizontally oriented capacitors is formed in the semiconductor element 100A. Each of these capacitors has significantly increased capacitance due to the nanotextured conductive surfaces formed across its dielectric layer. Depending on requirements, the semiconductor element 100A can comprise a plurality of vertically stacked horizontal capacitor plates, e.g., forming two stacked capacitors, three stacked capacitors, four stacked capacitors, five stacked capacitors, six stacked capacitors, seven stacked capacitors, eight stacked capacitors, nine stacked capacitors, or so forth. The multiple capacitors can be interconnected to form multiple serially and/or parallel connected capacitors. Furthermore, the different conductive layers, plates or electrodes, e.g., 106, 124, 134, 144, and 154 shown in FIG. 19, of the stacked capacitors can be interconnected so that the semiconductor element 100A can function as a variable capacitor.

Referring to FIG. 20, a schematic cross-sectional view of a semiconductor element 400 is illustrated as an alternative embodiment of the semiconductor element 100A described above. A fabrication process for forming the semiconductor element 400 of FIG. 20 starts from the stage shown in FIG. 1. A base nonconductive or dielectric layer 404 may be deposited over a base substrate 402, which can comprise a semiconductor material (e.g., single crystal silicon), and can include active devices (not shown). The dielectric layer 404 comprises a surface 418. A conductive layer 406 is provided over the dielectric layer 404. The conductive layer 406 can comprise a metal, such as copper, nickel, chromium, gold, indium, tin, platinum, silver, ruthenium, molybdenum, palladium, cobalt, zinc, tungsten, tantalum, titanium, aluminum, a metal silicide, and alloys thereof. A barrier layer may be provided between the conductive layer 406 and the underlying dielectric layer 404 to limit diffusion of the conductive material of the conductive layer 406 into the dielectric layer 404 and to serve as an adhesion layer therebetween, as with the semiconductor element 100A described previously. Subsequently, the conductive layer 406 is patterned by a mask layer 408, such as photoresist, to expose at least portions of a surface 416 of the underlying conductive layer 406.

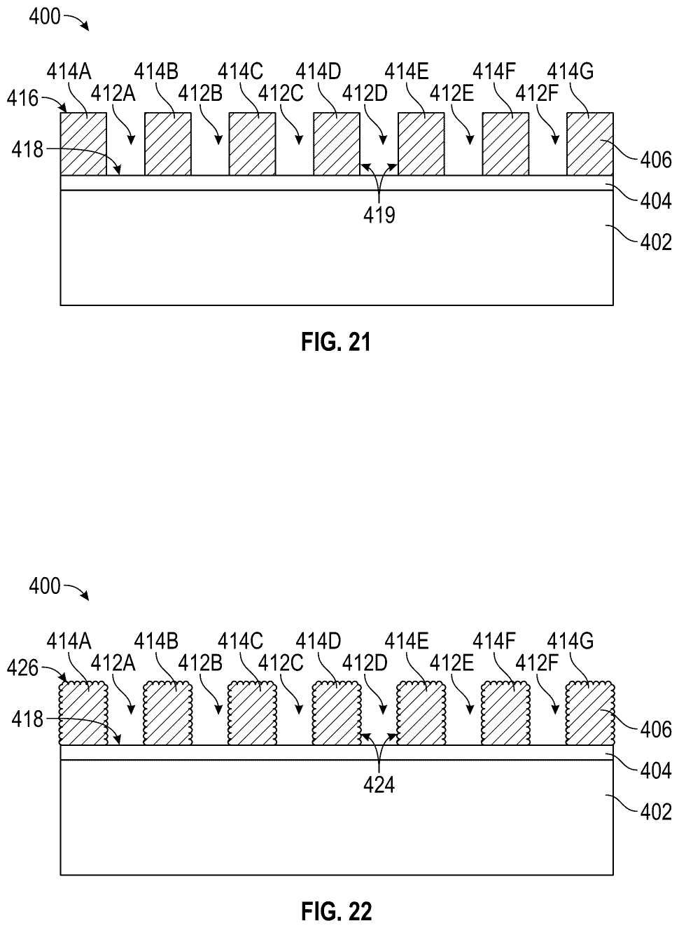

In FIG. 21, the conductive layer 406 is etched to form one or more trenches or cavities 412A-412F, which reach the surface 418 of the dielectric layer 404 and extends into and out of the paper in the cross-sectional view of the semiconductor element 400 shown in FIG. 21, so that conductive plates or lines 414A-414G formed from the conductive layer 406 are separated (e.g., electrically and mechanically separated) from each other. Each of the cavities 412A-412F is bounded by side surfaces or wall surfaces 419 of adjacent conductive lines. Six cavities 412A-412F are shown in FIG. 21. However, the number of trenches or cavities formed in the conductive layer 406 can be one, two, three, four, five, six, seven, eight, nine or another number as desired. As shown in FIG. 21, after the etching process the mask layer 408 is removed, and the surface 416 on each of the conductive lines 414A-414G is exposed.

In FIG. 22, the semiconductor element 400 goes through an oxidation process, e.g., an ashing process, followed by a reduction process, e.g., a forming gas annealing process. As such, the exposed surfaces of the conductive lines 414A-414G, including the side wall surfaces 419 and the surfaces 416, are converted into nanotextured metallic surfaces comprising metal nanograins, e.g., sidewall surfaces 429 and surfaces 426. The oxidation process, reduction process, and forming of nanotextured surfaces have been described in detail with respect to FIGS. 3-11, and is not further described herewith. The nanotextured surfaces 429, 426 after the oxidation and reduction processes have significantly increased surface area compared with the flat surfaces 419, 416. In other embodiments, the conductive lines 414A-414G may be formed by through-mask plating or by 3D printing. For the through-mask method, an adhesion layer, a seed layer or both may be provided over the dielectric layer 404. A patterned resist layer is formed over the seed layer to expose portions of the seed layer (e.g., first portions of the seed layer) and block other portions of the seed layer (e.g., second portions of the seed layer). The first portions of the seed layer may be selectively coated to a known thickness by electrodeposition, electroless plating, PVD, or other known method. After that, the resist layer is cleaned from the surface of the seed layer. The seed layer and the adhesive layer of the second portions of the seed layer are selectively removed to form the semiconductor element 400 of FIG. 22.

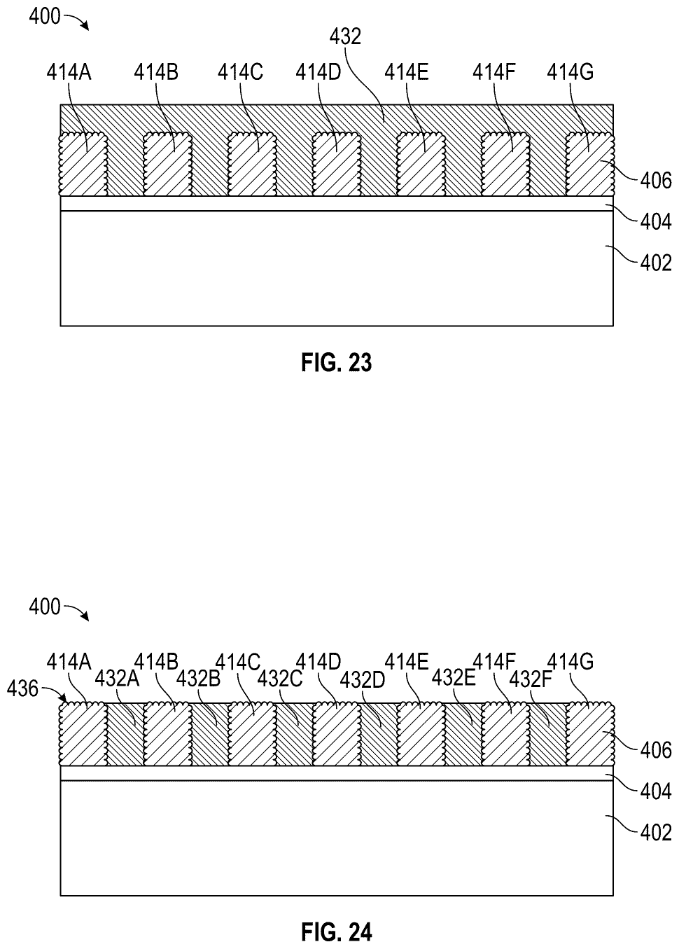

In FIG. 23, a dielectric material 432 overfills the cavities 412A-412F, including an overburden over the surfaces 426 of the conductive lines 414A-414G. The dielectric material 432 may comprise silicon nitride (SiN), hafnium oxide (HfO, such as HfO₂), aluminum oxide (AlO, such as Al₂O₃), tantalum oxide, titanium oxide, strontium titanate, barium strontium titanate, calcium copper titanate, or combinations thereof. Subsequently in FIG. 24, the excess dielectric material 432 disposed on the surfaces 426 of the conductive lines 414A-414G, and possibly top portions of the conductive lines 414A-414G, are removed to leave a planarized surface 436, such as by chemical mechanical planarization (CMP). The surface 436 comprises conductive portions on top of the conductive lines 414A-414G and dielectric portions on top of dielectric plates or lines 432A-432F, each of which disposed between two adjacent conductive lines. For example, the dielectric line 432A is disposed between the conductive line 414A and the conductive line 414B; the dielectric line 432B is disposed between the conductive line 414B and the conductive line 414C; the dielectric line 432C is disposed between the conductive line 414C and the conductive line 414D; the dielectric line 432D is disposed between the conductive line 414D and the conductive line 414E; the dielectric line 432E is disposed between the conductive line 414E and the conductive line 414F; the dielectric line 432F is disposed between the conductive line 414F and the conductive line 414G.

Thus, across each of the dielectric lines 432A-432F are a pair of conductive lines that can function as electrodes for a capacitor. Conductive surfaces facing each dielectric line are nanotextured conductive surfaces with increased surface areas, as described above. For example, the conductive line 414A and the conductive line 414B with the dielectric line 432A disposed therebetween can function as electrodes for a first capacitor; the conductive line 414C and the conductive layer 414D with the dielectric line 432C disposed therebetween can function as electrodes for a second capacitor; the conductive line 414E and the conductive line 414F with the dielectric line 432E disposed therebetween can function as electrodes for a third capacitor, etc. As such, a horizontal stack of multiple vertically oriented capacitors is formed in the semiconductor element 400. Each of these capacitors has significantly increased capacitance due to the nanotextured conductive surfaces formed across the dielectric line. Optionally, the semiconductor element 400 can comprise more than one horizontally stacked vertically oriented capacitors, e.g., two stacked capacitors, three stacked capacitors, four stacked capacitors, five stacked capacitors, six stacked capacitors, seven stacked capacitors, eight stacked capacitors, nine stacked capacitors, etc. The different conductive lines or electrodes, e.g., 414A-414G shown in FIG. 24, of the stacked capacitor plates can be interconnected so that the semiconductor element 400 can function as serially connected capacitors, parallelly connected capacitors, or a variable capacitor. For example, in a parallel arrangement, conductive lines 414A and 414C can connect to the same terminal, and conductive lines 414B and 414D can share a terminal.

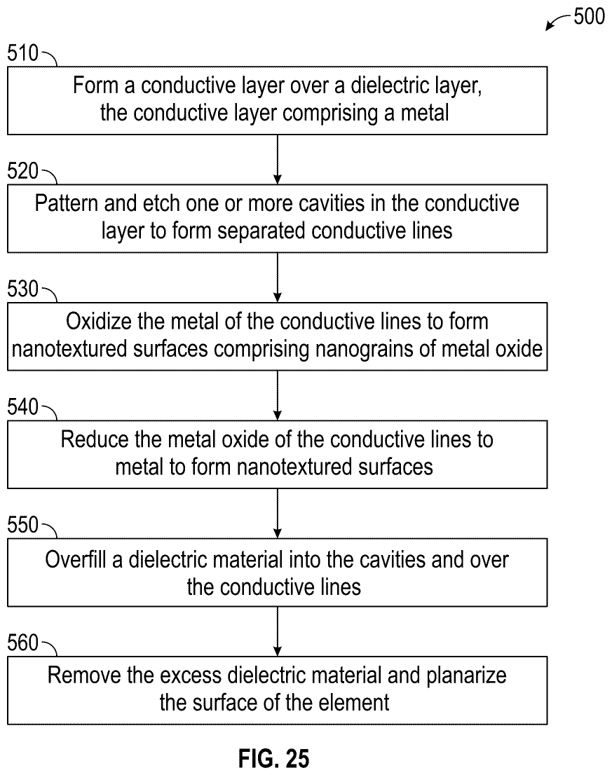

The fabrication method described above with respect to FIGS. 20-24 is further illustrated as a process flowchart 500 shown in FIG. 25. At block 510, a conductive layer having a surface is formed over a dielectric layer, which may be formed over a semiconductor substrate of a semiconductor element. The conductive layer comprises a metal. At block 520, the surface of the conductive layer is patterned to expose portion(s) of the conductive layer, and etch one or more cavities into the conductive layer to form conductive lines from the conductive layer. The conductive lines are separated by the cavity or cavities. At block 530, the conductive lines are oxidized to form nanotextured surfaces, including upper surfaces and side surfaces on the conductive lines. The nanotextured surfaces comprise nanograins of metal oxide. The nanotextured surfaces thus formed has significantly increased surface areas compared with flat surfaces before oxidation. At block 540, the metal oxide is reduced, and the topological structure of the nanotextured surface remains. At block 550, the cavities are overfilled with a dielectric material. The dielectric material may overburden the conductive lines. At block 560, excess dielectric material and possibly upper portions of the conductive lines are removed and the surface of the formed semiconductor element is planarized.

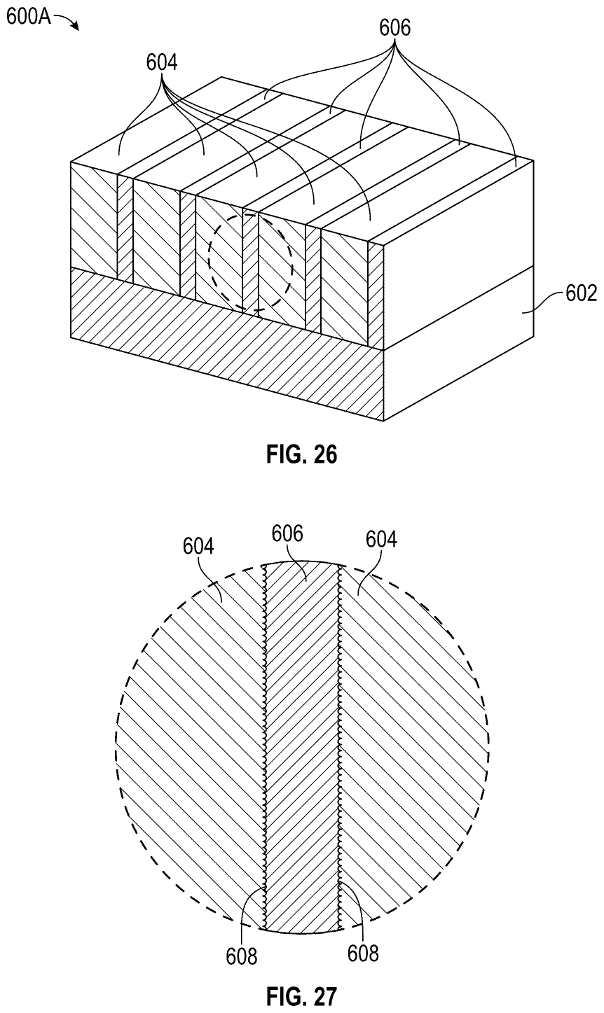

FIG. 26 shows a schematic perspective cross-sectional view of a capacitive semiconductor element 600A comprising horizontally stacked capacitor plates formed according to the method described above with respect to FIGS. 20-24, and the process flowchart 500 shown in FIG. 25. As shown in FIG. 26, the semiconductor element 600A comprises a base substrate 602, a plurality of vertically oriented conductive plates 604 over the substrate 602, and a plurality of dielectric layers 606 provided over the substrate 602 and juxtaposed with the plurality of conductive plates 604, the conductive plates 604 being much wider than the dielectric layers 606. In some embodiments, each conductive plate 604 is at least 10 to 50,000 times wider than each of the dielectric layers 606. Each of the dielectric layers 606 is disposed between two adjacent conductive plates 604. As such, the adjacent conductive plates 604 with a single dielectric layer 606 disposed therebetween can function as a capacitor. As described with respect to FIG. 24 above, the vertically oriented conductive plates 604 and dielectric layers 606 as illustrated in FIG. 26 can function as a horizontal stack of capacitors. FIG. 27 illustrates a detail cross-sectional view of two adjacent conductive plates 604 and one dielectric layer 606 disposed therebetween. As shown, side surfaces of the conductive plates 604 are characterized by nanograins, thus forming nanotextured surfaces 608. As described above, the nanotextured surfaces 608 can be formed by oxidation and reduction processes, and can significantly increase the surface area, thus increasing capacitance. Similar to the previously described stacks, the conductive plates 604 can be interconnected to function as a plurality of serially or parallelly connected capacitors, or as a variable capacitor.

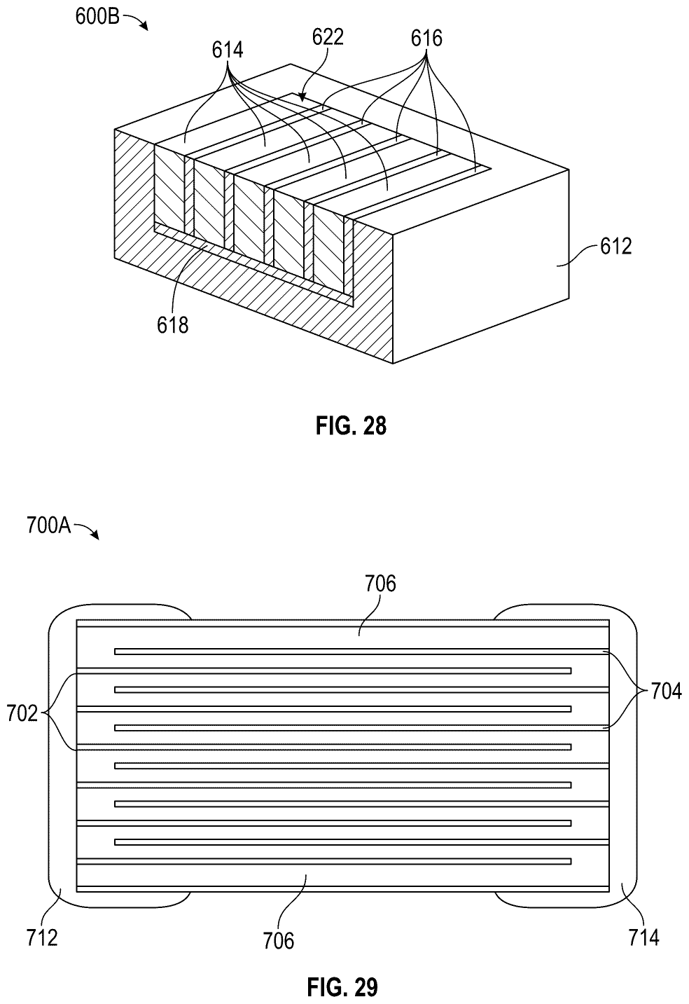

An alternative embodiment of the semiconductor element 600A shown in FIG. 26 is illustrated in FIG. 28 as a semiconductor element 600B. In FIG. 28, vertically oriented conductive plates 614 and dielectric layers 616 are formed in a cavity 622, over a dielectric layer 618. The cavity 622 is formed in a dielectric layer or substrate 612.

The embodiments of capacitors having nanotextured conductive surfaces disclosed herein can be implemented in different styles, shapes and structures and can be built by different fabrication methods. As shown in the plan view of FIG. 29, a semiconductor element 700A comprises first horizontal electrodes 702 and second horizontal electrodes 704 that are disposed in parallel. The first horizontal electrodes 702 and the second horizontal electrodes 704 are juxtaposed and interdigitated. Both the first horizontal electrodes 702 and the second horizontal electrodes 704 comprise a conductive metal. As shown in FIG. 29, each of the first horizontal electrodes 702 except for the one at the top edge thereof is disposed between two adjacent second horizontal electrodes 704. In other words, each first horizontal electrode 702 except for the one at the top edge is bounded by two adjacent second horizontal electrodes 702. Likewise, each second horizontal electrode 704 except for the one at the bottom edge is disposed between two adjacent first horizontal electrodes 702. The first horizontal electrodes 702 are connected to a first terminal 712 at the left side, and the second horizontal electrodes 704 are connected to a second terminal 714 at the right side. Dielectric material layers 706 are provided into the space between adjacent first and second electrodes to separate the electrodes. When the first terminal 712 and the second terminal 714 are connected to a circuit, the semiconductor element 700A acts as a capacitor with an electric capacitance to accumulate electric charges and store electrical energy. The horizontal parallel electrodes, including the first horizontal electrodes 702 and the second horizontal electrodes 704 and the dielectric material layers 706 disposed between the adjacent electrodes can be fabricated by thin film fabrication methods, such as the methods described with respect to FIGS. 1-25. When the metal or metals in the electrodes 702 and 704 are oxidized and reduced to form nanotextured surfaces on the electrodes, surface areas are significantly increased. As such electric capacitance of the capacitor of the semiconductor 700A can be significantly improved.

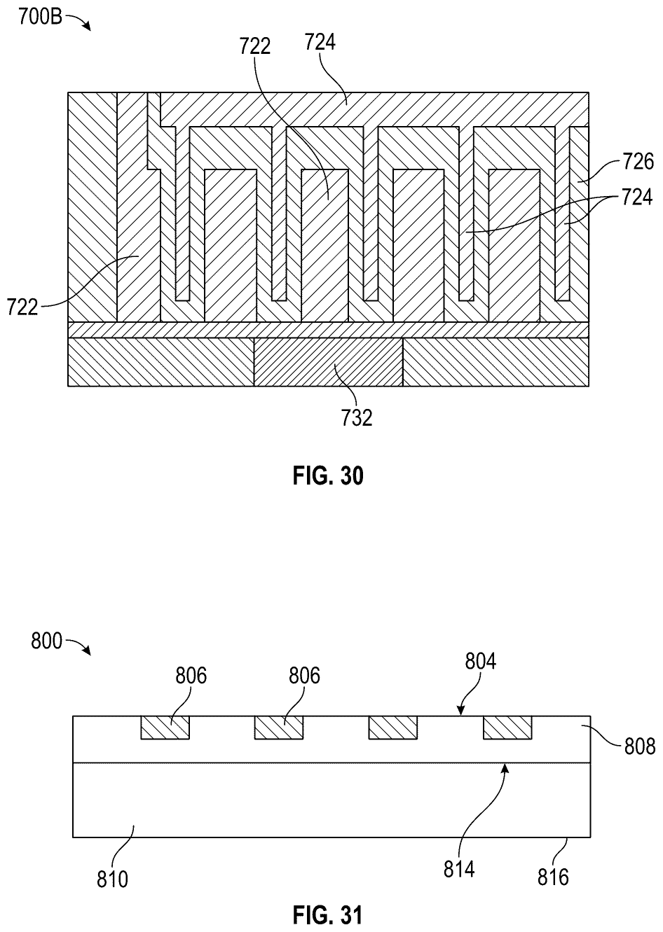

FIG. 30 schematically illustrates another example implementation of nanotextured surfaces in a semiconductor element 700B, which comprises first vertical plates 722 that are juxtaposed with each other. The first vertical plates 722 comprise conductive material, e.g., a metal. The first vertical plates 722 are connected to a first terminal 732 at the bottom through an intervening conductive layer, such that all the first vertical plates 722 serve as a first electrode together. A layer of dielectric material 726 is provided over and into the spaces between adjacent first plates 722. A second electrode 724 is formed by a conductive material deposited conformally over the dielectric material layer 726 and into cavities formed in the dielectric material 726 in spaces between the first vertical plates 722 as parallel plates. When the first terminal 732 and the second electrode 724 are connected to a circuit, the semiconductor element 700B acts as a capacitor with an electric capacitance to accumulate electric charges and store electrical energy. The vertical parallel plates or electrodes, including the first vertical electrodes 722, the vertical plates of the second vertical electrode 724, and the dielectric material layers 726 disposed between the adjacent electrodes can be fabricated by thin film fabrication methods, such as the methods described with respect to FIGS. 20-27. For example, the first vertical plates 722 can be first formed as pillars, lines or rings, the surfaces oxidized and reduced for nanotexturing as taught herein. The dielectric layer 726 can then be conformally deposited thereover, and the conductor for the second electrode 724 can be conformally deposited over the dielectric layer 762. When the metal or metals in the electrodes 722 and 724 are oxidized and reduced to form nanotextured surfaces on the electrodes, surface areas can be significantly increased. Electric capacitance of the capacitor can therefore be significantly improved. FIG. 30 illustrates an example of a three-dimensional (3D) folding shape that can be formed by conventional semiconductor processing to produce a high surface area microstructure, the surface area of which can be further enhanced by nanotexturing as described herein. Other 3D shapes include container shapes, tubes, pillars, rings, and fins, etc.

For general description of semiconductor structures for which the nanotextured capacitor structures described herein can be useful, FIG. 31 schematically illustrates a cross-sectional view of an element 800 according to some embodiments. The element 800 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the element 800, and BEOL interconnect layers over such semiconductor portions. An upper layer 808 can be provided as part of such BEOL layers during device fabrication, as part of RDLs, or as specific bonding layers added to existing devices, with bond pads extending from underlying contacts. Active devices and/or circuitry can be patterned and/or otherwise disposed in or on a base substrate portion 810, and can electrically communicate with at least some of conductive features 806. The conductive features 806 can serve as contacts for communication with other microelectronic devices. Capacitors, as described herein, can be formed in or above the base substrate portion 810. Active devices and/or circuitry can be disposed at or near the front side 804 of the base substrate portion 810, and/or at or near opposite backside 816 of the base substrate portion 810. In other embodiments, the base substrate portion 810 may not include active circuitry and need not comprise semiconductor material, but may instead comprise insulating material, a passive interposer, passive optical element (e.g., glass substrates, gratings, lenses), etc. The element 800 can comprise a stand-alone capacitor, such as a surface mount device. The upper layer 808 is shown as being provided on the front side of the elements, but similar layer can be additionally or alternatively provided on the back side of the element 800.

In some arrangements, the element 800 can comprise a singulated element, such as a singulated integrated device die. In other arrangements, the element 800 can comprise a carrier or substrate (e.g., a semiconductor wafer) that includes a plurality (e.g., tens, hundreds, or more) of device regions that, when singulated, forms a plurality of integrated device dies, including capacitors as described herein, though in other embodiments such a carrier can be a package substrate or a passive or active interposer. The element 800 can be connected to other microelectronic elements of a larger system by way of the conductive features 806, such as by direct bonding, e.g., hybrid bonding, of the element 800 to another microelectronic element or semiconductor element, e.g., adopting a uniform direct bonding processes include the ZIBOND® techniques commercially available from Adeia of San Jose, CA, or by solder bumps or thermocompression bonding.

In one aspect of the disclosure, a method for forming a capacitive element comprises providing a first conductive layer having a metal, and oxidizing the metal in the first conductive layer to form a metal oxide. At least part of the metal oxide forms nanograins in the first conductive layer. The method further comprises reducing the metal oxide to the metal to form a nanotextured metal surface, providing a dielectric layer over the first conductive layer, and providing a second conductive layer over the dielectric layer.

In some embodiments, the metal of the first conductive layer comprises copper, nickel, chromium, gold, indium, tin, platinum, silver, ruthenium, molybdenum, palladium, cobalt, zinc, tungsten, tantalum, titanium, aluminum, a metal silicide, or an alloy thereof. In some embodiments, the dielectric layer comprises silicon nitride, hafnium oxide, aluminum oxide, tantalum oxide, titanium oxide, strontium titanate, barium strontium titanate, calcium copper titanate, calcium copper titanium oxide, or a combination thereof.

In some embodiments, the dielectric layer has a substantially uniform thickness. For example, the thickness of the dielectric layer is less than 50 nm, or less than 20 nm.

In some embodiments, oxidizing the metal comprises plasma oxidization, thermal oxidization, ozone exposure, or wet oxidation of the metal. In some embodiments, oxidizing the metal forms the nanotextured surface of the metal oxide on the first conductive layer. In some embodiments, reducing the metal oxide comprises exposing the metal oxide to hydrogen-containing plasma, water vapor plasma, hydrogen gas, or forming gas.

In some embodiments, the first conductive layer and the second conductive layer function as electrodes of a capacitor. In some embodiments, a lower surface of the second conductive layer comprises a 3D topological surface structure transferred from the nanotextured metal surface of the first conductive layer. In some embodiments, the first conductive layer and the second conductive layer are separated by the dielectric layer. In some embodiments, the first conductive layer is provided over a dielectric layer or a semiconductor substrate.

In another aspect of the disclosure, the method for forming a capacitive element further comprises oxidizing a metal in the second conductive layer to form a metal oxide, where at least part of the metal oxide forms nanograins in the second conductive layer, reducing the metal oxide formed in the second conductive layer to the metal to form a second nanotextured metal surface on the second conductive layer, providing a second dielectric layer over the second nanotextured metal surface, and providing a third conductive layer over the second dielectric layer. In some embodiments, the method for forming a capacitive element further comprises repeating the process of oxidizing the metal in the second conductive layer and reducing the metal oxide formed in the second conductive layer to form the nanotextured metal surface on the second conductive layer, and providing subsequent dielectric and conductive layers until the capacitive element is formed. In some embodiments, the second dielectric layer has a substantially uniform thickness.

In another aspect of the disclosure, a method for forming a microelectronic device having at least one capacitor comprises forming two or more conductive plates comprising a metal, exposing the two or more conductive plates to an oxidizing environment to oxidize at least part of the metal in the two or more conductive plates to a metal oxide, exposing the two or more conductive plates to a reducing environment to convert at least part of the metal oxide to the metal to convert surfaces of the two of more conductive plates to nanotextured metal surfaces, and filling a dielectric material into a space between each adjacent pair of the two or more conductive plates.

In some embodiments, forming the two or more conductive plates comprising a damascene process.

In some embodiments, the two or more conductive plates are substantially parallel to one another.

In some embodiments, the metal comprises copper. In some embodiments, the dielectric material comprises silicon nitride, hafnium oxide, or aluminum oxide.

In some embodiments, exposing the two or more conductive plates to the oxidizing environment comprises plasma oxidizing, thermal oxidizing, ozone exposure, or wet oxidation of the metal. In some embodiments, the exposing the two or more conductive plates to the reducing environment comprises a hydrogen-containing plasma reduction, a water vapor plasma reduction, a hydrogen gas reduction, or a forming gas annealing. For example, exposing the two or more conductive plates to the reducing environment comprises a forming gas annealing at about 1 milliTorr to 1000 milliTorr and about 80° C. to 250° C. for about 3 minutes to 90 minutes, or at about 100 milliTorr to 10000 milliTorr and about 50° C. to 300° C. for about 10 minutes to 60 minutes.

In some embodiments, the two or more conductive plates comprise multiple adjacent pairs of conductive plates, wherein each pair functions as two electrodes of a capacitor.

In some embodiments, the method for forming a microelectronic device having at least one capacitor further comprises removing excess dielectric material over the two or more conductive plates after filling the dielectric material.

In another aspect of the disclosure, a process for forming a semiconductor element having one or more stacked capacitors comprises providing two or more conductive lines that are substantially parallel with one another, and providing one or more dielectric lines. The two or more conductive lines and the one or more dielectric lines are juxtaposed and interdigitated. The method further comprises oxidizing a metal to form a metal oxide on a surface of at least some of the two or more conductive lines to form surface-oxidized conductive lines, where at least part of the metal oxide forms nanograins in each of the surface-oxidized conductive lines and at least partially reducing the metal oxide to the metal to form a nanotextured metal surface on each of the surface-oxidized conductive lines.

In some embodiments, each of the one or more dielectric lines is disposed between two adjacent conductive lines. In some embodiments, each of the two adjacent conductive lines has a nanotextured surface facing each another. In some embodiments, at least one of the two nanotextured surfaces of the two adjacent conductive lines is the nanotextured metal surface.

In some embodiments, the two or more conductive lines and the one or more dielectric lines are horizontally oriented. In some embodiments, the two or more conductive lines and the one or more dielectric lines are vertically oriented.

In some embodiments, the two or more conductive lines and the one or more dielectric lines are provided layer by layer. In some embodiments, the two or more conductive lines are provided simultaneously. In some embodiments, the one or more dielectric lines are provided after providing the two or more conductive lines.

In some embodiments, the metal comprises copper. In some embodiments, the one or more dielectric lines comprise silicon nitride, hafnium oxide, or aluminum oxide.

In some embodiments, a thickness of each of the one or more dielectric lines is less than 50 nm, or less than 20 nm. In some embodiments, a thickness of each of the two or more conductive lines is at least 10 times larger than a thickness of each of the one or more dielectric lines.

In another aspect of the disclosure, a semiconductor element comprises a first conductive layer comprising a surface portion that has nanograins of a metal forming a first nanotextured surface thereon, a second conductive layer having a second nanotextured surface, and a dielectric layer disposed between the first conductive layer and the second conductive layer, where the first nanotextured surface and the second nanotextured surface are facing each other.

In some embodiments, a density of the nanograins of the metal in the first conductive layer is the highest at the first nanotextured surface and decreases with a distance away from the first nanotextured surface and into the first conductive layer.

In some embodiments, an oxygen content in an upper portion of the first conductive layer is greater than 100 ppm.

In some embodiments, the metal comprises copper. In some embodiments, the dielectric comprises silicon nitride, hafnium oxide, or aluminum oxide.

In another aspect of the invention, a method for forming a capacitive element comprises providing a first conductive layer comprising a conductive material, chemically converting at least a portion of the conductive material to form a compound of the conductive material, where at least part of the compound forming nanograins in the first conductive layer, chemically converting at least part of the compound back to the conductive material to form a nanotextured conductive surface on the first conductive layer, providing a dielectric layer over the nanotextured conductive surface, and providing a second conductive layer over the dielectric layer.

In some embodiments, chemically converting at least a portion of the conductive material to form a compound of the conductive material includes chemically oxidizing at least a portion of a metal to form a metal oxide. In some embodiments, chemically converting at least part of the compound back to the conductive material includes chemically reducing the metal oxide to metal.

In some embodiments, the conductive material comprises copper, nickel, chromium, gold, indium, tin, platinum, silver, ruthenium, molybdenum, palladium, cobalt, zinc, tungsten, tantalum, titanium, aluminum, a metal silicide, or an alloy thereof. In some embodiments, the dielectric layer comprises silicon nitride, hafnium oxide, aluminum oxide, or a combination thereof.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions, and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A method for forming a capacitive element, comprising:
providing a first conductive layer comprising a metal;
at least partially oxidizing the metal in the first conductive layer to form a metal oxide, at least part of the metal oxide forming nanograins in the first conductive layer;
at least partially reducing the metal oxide to the metal to form a first nanotextured metal surface;
providing a dielectric layer over the first conductive layer; and
providing a second conductive layer over the dielectric layer.

2. The method of claim 1, wherein the metal comprises copper, nickel, chromium, gold, indium, tin, platinum, silver, ruthenium, molybdenum, palladium, cobalt, zinc, tungsten, tantalum, titanium, aluminum, a metal silicide, or an alloy thereof.

3. The method of claim 1, wherein the dielectric layer comprises silicon nitride, hafnium oxide, aluminum oxide, tantalum oxide, titanium oxide, strontium titanate, barium strontium titanate, calcium copper titanate, or a combination thereof.

4. The method of claim 1, wherein the dielectric layer has a substantially uniform thickness.

5. The method of claim 4, wherein the thickness of the dielectric layer is less than 50 nm.

6. (canceled)

7. The method of claim 1, wherein oxidizing the metal comprises plasma oxidization, thermal oxidization, ozone exposure, or wet oxidation of the metal.

8. The method of claim 1, wherein oxidizing the metal forms a nanotextured surface of the metal oxide on the first conductive layer.

9. The method of claim 1, wherein reducing the metal oxide comprises exposing the metal oxide to hydrogen-containing plasma, water vapor plasma, hydrogen gas, or forming gas.

10. (canceled)

11. The method of claim 1, wherein a lower surface of the second conductive layer comprises a 3D topological surface structure transferred from the nanotextured metal surface of the first conductive layer.

12.-13. (canceled)

14. The method of claim 1, further comprising:
at least partially oxidizing a metal in the second conductive layer to form a metal oxide, at least part of the metal oxide forming nanograins in the second conductive layer;
at least partially reducing the metal oxide in the second conductive layer to the metal to form a second nanotextured metal surface on the second conductive layer;
providing a second dielectric layer over the second nanotextured metal surface; and
providing a third conductive layer over the second dielectric layer.

15. The method of claim 14, further comprising:
repeating the process of oxidizing the metal in the second conductive layer and reducing the metal oxide formed in the second conductive layer to form the nanotextured metal surface on the second conductive layer; and
providing subsequent dielectric and conductive layers until the capacitive element is formed.

16. (canceled)

17. A method for forming a microelectronic device having at least one capacitor, comprising:
forming two or more conductive plates comprising a metal;
exposing the two or more conductive plates to an oxidizing environment to oxidize at least part of the metal in the two or more conductive plates to a metal oxide;
exposing the two or more conductive plates to a reducing environment to convert at least part of the metal oxide to the metal to convert surfaces of the two of more conductive plates to nanotextured metal surfaces; and
filling a dielectric material into a space between each adjacent pair of the two or more conductive plates.

18.-19. (canceled)

20. The method of claim 17, wherein the metal comprises copper.

21. The method of claim 17, wherein the dielectric material comprises silicon nitride, hafnium oxide, or aluminum oxide.

22. The method of claim 17, wherein exposing the two or more conductive plates to the oxidizing environment comprises plasma oxidizing.

23. (canceled)

24. The method of claim 17, wherein exposing the two or more conductive plates to the reducing environment comprises a forming gas annealing at about 1 milliTorr to 1000 milliTorr and about 80° C. to 250° C. for about 3 minutes to 90 minutes.

25. (canceled)

26. The method of claim 17, wherein the two or more conductive plates comprise multiple adjacent pairs of conductive plates, wherein each pair functions as two electrodes of a capacitor.

27. (canceled)

28. A process for forming a semiconductor element having one or more stacked capacitors, comprising:
providing two or more conductive lines, the two or more conductive lines substantially parallel with one another;
providing one or more dielectric lines, wherein the two or more conductive lines and the one or more dielectric lines are juxtaposed and interdigitated;
at least partially oxidizing a metal to form a metal oxide on a surface of at least some of the two or more conductive lines to form surface-oxidized conductive lines, at least part of the metal oxide forming nanograins in each of the surface-oxidized conductive lines; and
at least partially reducing the metal oxide to the metal to form a nanotextured metal surface on each of the surface-oxidized conductive lines.

29. The process of claim 28, wherein each of the one or more dielectric lines is disposed between two adjacent conductive lines.

30. The process of claim 29, wherein each of the two adjacent conductive lines has a nanotextured surface facing each another.

31. The process of claim 30, wherein at least one of the two nanotextured surfaces of the two adjacent conductive lines is the nanotextured metal surface.

32. The process of claim 28, wherein the two or more conductive lines and the one or more dielectric lines are horizontally oriented.

33. The process of claim 28, wherein the two or more conductive lines and the one or more dielectric lines are vertically oriented.

34.-36. (canceled)

37. The process of claim 28, wherein the metal comprises copper.

38.-51. (canceled)
